(19) United States
(12) Patent Application Publication
(10) Pub. No.: US 2021/0387919 A1
(43) Pub. Date: Dec. 16, 2021

(54) CERAMIC TUBE

(71) Applicant: KYOCERA Corporation, Kyoto-shi, Kyoto (JP)

(72) Inventor: Manpei TANAKA, Higashiomi-shi, Shiga (JP)

(21) Appl. No.: 17/287,381

(22) PCT Filed: Oct. 11, 2019
(86) PCT No.: PCT/JP2019/040333

§ 371 Date: Apr. 21, 2021

(30) Foreign Application Priority Data
Oct. 29, 2018 (JP) 2018-202877

(51) Int. Cl. C04B 35/505; H01J 37/32; C04B 35/634; C04B 35/64

(52) U.S. Cl. CPC C04B 35/505; H01J 37/3244; H01L 21/3065; C04B 35/64; H01J 2237/334; C04B 35/634

(57) ABSTRACT

A ceramic tube contains yttrium oxide as a main component, in which the section height difference (Rδc) of the roughness profile of an inner peripheral surface, which represents a difference between a section level at a load length ratio of 25% in the roughness profile and a section level at load length ratio of 75% in the roughness profile, is 2 μm or less and a coefficient of variation of the section height difference (Rδc) is 0.05 to 0.6.

### TECHNICAL FIELD

The present disclosure relates to a ceramic tube and a plasma processing apparatus.

### BACKGROUND

Conventionally, in each step such as etching and film formation in manufacturing semiconductors or liquid crystals, plasma is used to process an object to be processed. In this step, corrosive gas containing halogen elements such as fluorine and chlorine which are highly reactive is used. Therefore, high corrosion resistance is required for a member that contacts with the corrosive gas and its plasma used in an apparatus for manufacturing semiconductors or liquid crystals. As such a member, Patent Document 1 suggests a gas nozzle of Y₂O₃ sintered body in which an inner surface through which corrosive gas flows is a surface as it is sintered, and an outer surface exposed to the corrosive gas or plasma of the corrosive gas is roughened. It is described that the roughening of the outer surface is performed by a blasting process.

Further, Patent Document 2 describes a gas nozzle containing yttria as a main component, in which a molded body obtained by a CIP (Cold Isostatic Pressing) molding method is sintered in an air atmosphere at 1400 to 1700° C., and then a through hole is formed by grinding.

### PRIOR ART DOCUMENTS

### Patent Documents

Patent Document 1: Japanese Unexamined Patent Publication No. 2007-63595

Patent Document 2: International Publication No. 2013/065666

### SUMMARY

A ceramic tube of the present disclosure is a ceramic tube containing yttrium oxide as a main component, in which the section height difference (Rδc) of the roughness profile of an inner peripheral surface, which represents a difference between a section level at a load length ratio of 25% in the roughness profile and a section level at a load length ratio of 75% in the roughness profile, is 2 μm or less, and a coefficient of variation of the section height difference (Rδc) is 0.05 to 0.6.

### BRIEF DESCRIPTION OF THE DRAWINGS

FIG. 1(a) is a sectional view illustrating a part of a plasma processing apparatus provided with an upper electrode to which a gas passage tube, which is a plasma-processing apparatus member of the present disclosure, is attached.

FIG. 1 (b) is an enlarged view of the part A in FIG. 1(a).

### EMBODIMENT

Hereinafter, the ceramic tube and the plasma processing apparatus according to the embodiment of the present disclosure are described in detail with reference to the drawings. However, in all the figures of the present description, the same parts are designated by the same reference numerals and the description thereof will be omitted as appropriate unless confusion occurs.

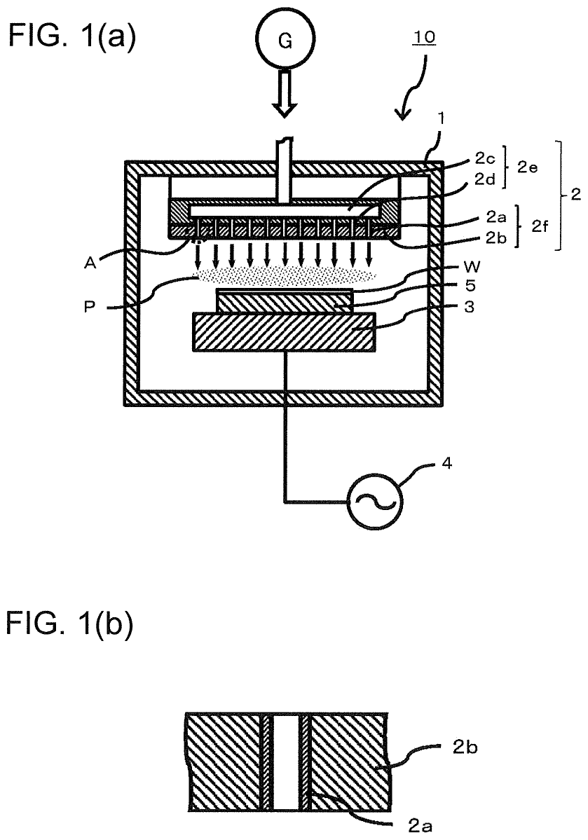

FIG. 1(a) is a sectional view illustrating a part of a plasma processing apparatus provided with an upper electrode to which a gas passage tube, which is a plasma-processing apparatus member of the present disclosure, is attached, and FIG. 1 (b) is an enlarged view of the part A in FIG. 1(a).

The plasma processing apparatus 10 of the present disclosure shown in FIG. 1(a) is, for example, a plasma etching apparatus, and has a chamber 1 in which a workpiece W such as a semiconductor wafer is arranged, an upper electrode 2 arranged on the upper side in the chamber 1, and a lower electrode 3 arranged on the lower side and opposed to the upper electrode 2.

The upper electrode 2 includes an electrode plate 2b having a large number of gas passage pipes 2a for supplying a plasma generating gas G into the chamber 1, and a holding member 2e having a diffusion part 2c which is an internal space for diffusing the plasma generating gas G internally and a large number of introduction holes 2d for introducing the diffused plasma generating gas G into the gas passage pipes 2a.

Then, the plasma generating gas G discharged in the form of a shower from the gas passage pipes 2a becomes plasma by supplying high frequency power from a high frequency power supply 4, and then it forms a plasma space P. The electrode plate 2b and the gas passage pipes 2a may be collectively referred to as a shower plate 2f.

In FIG. 1(a), since the gas passage pipes 2a are small, only the positions are shown, and the detailed configuration is shown in FIG. 1(b).

Among these members, for example, the upper electrode 2, the lower electrode 3, and the high frequency power supply 4 form a plasma generating apparatus.

Examples of the plasma generating gas G include fluorine-based gases such as SF₆, CF₄, CHF₃, ClF₃, NF₃, C₄F₈, and HF, and chlorine-based gases such as Cl₂, HCl, BCl₃, and CCl₄. The gas passage pipe 2a is an example of a ceramic tube. Hereinafter, the gas passage pipe 2a may be referred to as a plasma-processing apparatus member 2a.

The lower electrode 3 is, for example, a susceptor made of aluminum, and an electrostatic chuck 5 is placed on the susceptor and holds the workpiece W by an electrostatic adsorption force. Then, a coating film formed on the surface of the workpiece W is etched by ions and radicals contained in plasma.

The gas passage pipe 2a, which is formed of the ceramic tube of the present disclosure, contains yttrium oxide as a main component, and its inner peripheral surface and discharge side end surface become surfaces exposed to the plasma generating gas G. The gas passage pipe 2a has, for example, an outer diameter of 2 to 4 mm, an inner diameter of 0.4 to 0.6 mm, and a height of 3 to 7 mm.

Yttrium oxide is a component having high corrosion resistance to the plasma generating gas G. The ceramic tube of the present disclosure has higher corrosion resistance as the content of yttrium oxide is higher. Particularly, the content of yttrium oxide may be 98.0% by mass or more, 99.5% by mass or more, and further 99.9% by mass or more.

Further, in addition to yttrium oxide, for example, at least one element of silicon, iron, aluminum, calcium and magnesium may be contained, the content of silicon may be 300 mass ppm or less in terms of SiO₂, the content of iron may be 50 mass ppm or less in terms of Fe₂O₃, the content of aluminum may be 100 mass ppm or less in terms of Al₂O₃, and the contents of calcium and magnesium may be 350 mass ppm or less in total in terms of CaO and MgO, respectively. Further, the content of carbon may be 100 mass ppm or less.

The components constituting the ceramics can be identified by using an X-ray diffraction apparatus (XRD) using CuKα rays, and then the content of the element can be determined by using an X-ray fluorescence analyzer (XRF) or an ICP emission spectrophotometer (ICP) and converted to the content of the identified components. The content of carbon can be determined by using a carbon analyzer.

In the ceramic tube of the present disclosure, the section height difference (Rδc) of the roughness profile of an inner peripheral surface, which represents a difference between a section level at a load length ratio of 25% in the roughness profile and a section level at load length ratio of 75% in the roughness profile, is 2 μm or less and a coefficient of variation of the section height difference (Rδc) is 0.05 to 0.6.

As shown in the following formula (1), a load length ratio Rmr is a ratio of a sum of cut lengths η1, η2, . . . , ηn (load length ηp) obtained by extracting a reference length L from a roughness profile defined by JIS B0601: 2001 in the direction of its average line and cutting the roughness profile of the extracted part at a section level parallel to the top line, with respect to the reference line L, expressed by a percentage. The load length ratio Rmr indicates surface properties in a height direction and a direction perpendicular to the height direction.

Rmr=ηp/L×100

np: η1+η2+ . . . +ηn(1)

A section level C (Rrmr) corresponding to each of the two types of load length ratios, corresponding to such a load length ratio Rmr, and the section height difference (Rδc) indicating the difference between these section levels C (Rrmr) also correspond to the surface properties in the height direction of the surface and the direction perpendicular to the height direction. If the section height difference (Rδc) is large, unevenness of the surface to be measured is large, while if it is small, the unevenness of the surface is small and relatively flat.

The coefficient of variation of the section height difference (Rδc) is a value represented by √V1/X1 when a standard deviation of the section height difference (Rδc) is √V1 and a mean value of the section height difference (Rδc) is X1.

If the section height difference (Rδc) of the roughness profile of the inner peripheral surface is 2 μm or less and the coefficient of variation of the section height difference (Rδc) is 0.6 or less, the unevenness of the inner peripheral surface is small and relatively flat, and moreover the variation in the unevenness of the inner peripheral surface is small, so that generation of particles can be suppressed. Further, if the section height difference (Rδc) of the roughness profile of the inner peripheral surface is 2 μm or less and the coefficient of variation of the section height difference (Rδc) is 0.05 or more, although the unevenness of the inner peripheral surface is small and relatively flat, there is a slight variation in the unevenness of the inner peripheral surface, and thus floating particles can be easily captured and scattering of the particles can be suppressed.

Further, a mean value of the root mean square slope (Rq) of the roughness profile may be 3.5 μm or less, and a coefficient of variation of the root mean square slope (Rq) may be 0.05 to 0.6. If the mean value and the coefficient of variation of the root mean square slope (Rq) are in the above ranges, the unevenness of the inner peripheral surface is smaller and flatter, and moreover the variation of the unevenness of the inner peripheral surface is further reduced, and thus the effect of suppressing the generation and scattering of the particles is enhanced.

Here, the coefficient of variation of the root mean square slope (Rq) is a value represented by √V₂/X₂ when a standard deviation of the root mean square slope (Rq) is √V₂ and the mean value of the root mean square slope (Rq) is X₂.

In the present disclosure, the section height difference (Rδc) and the root mean square slope (Rq) of the roughness profile can both be obtained by using a laser microscope device having a measurement mode according to JIS B 0601: 2001 (for example, VK-9510 manufactured by KEYENCE CORPORATION). If the laser microscope VK-9510 is used, values indicating each of the above surface properties can be obtained for each measurement range by setting, for example, a measurement mode to be color ultra-depth, a gain to be 953, a measurement magnification to be 400 times, a measurement range per point to be 295 μm to 360 μm×150 μm to 230 μm, a measurement pitch to be 0.05 μm, a profile filter λs to be 2.5 μm and a profile filter λc to be 0.08 mm. For example, the points to be measured can be eight points including four points at both end parts and four points at the center parts of the ceramic tube, and the mean value and the coefficient of variation of the section height difference (Rδc) and the mean value and the coefficient of variation of the root mean square slope (Rq) may be calculated by using the measured values of these eight points.

Further, the ceramic tube of the present disclosure may contain at least one of iron, cobalt and nickel, and the total content of these metal elements may be 0.1% by mass or less. If the total content of these metal elements is 0.1% by mass or less, the ceramic tube can be made non-magnetic, so that the ceramic tube can be used as a member of a device that requires suppression of influences of magnetic of, for example, an electron boom exposure device or the like. The content of each of these metal elements can be determined by using a glow discharge mass spectrometer (GDMS).

The ceramic tube of the present disclosure may contain a larger amount of yttrium aluminum oxide in the inner peripheral surface than the outer peripheral surface located on the opposed side of the inner peripheral surface. With such a configuration, since the corrosion resistance of the inner peripheral surface directly exposed to the plasma generating gas G becomes higher than the outer peripheral surface exposed to plasma generating gas G, it can be used for a long period of time. The composition formula of yttrium silicate is represented as, for example, Y₂SiO₅ and Y₂Si₂O₇.

Further, in the ceramic tube of the present disclosure, a maximum peak intensity I₁ on the inner peripheral surface of yttrium silicate (Y₂SiO₅) occurring at a diffraction angle 2θ of 30° to 32° may be larger than a maximum peak intensity I₂ on the outer peripheral surface of yttrium silicate (Y₂SiO₅) occurring at a diffraction angle 2θ of 30° to 32°.

With such a constitution, yttrium silicate (Y₂SiO₅) contained in the inner peripheral surface has higher crystallinity than yttrium silicate (Y₂SiO₅) contained in the outer peripheral surface, so that a strong compressive stress is applied to the amorphous part and crystal particles of yttrium oxide (Y₂SiO₅) in the inner peripheral surface rather than the outer peripheral surface, and when the plasma generating gas G is supplied to the introduction hole 2d, particles generated from the grain boundary phase can be suppressed.

Next, an example of the method for manufacturing the ceramic tube of the present disclosure will be described.

First, a powder containing yttrium oxide as a main component, a wax, a dispersant and a plasticizer are prepared. With respect to 100 parts by mass of a powder containing yttrium oxide with a purity of 99.9% as a main component (hereinafter referred to as yttrium oxide powder), the wax is set to be 13 to 14 parts by mass, the dispersant is set to be 0.4 to 0.5 parts, and the plasticizer is set to be 1.4 to 1.5 parts by mass.

Then, the yttrium oxide powder, the wax, the dispersant, and the plasticizer, all of which are heated to 90° C. or higher, are contained in a container made of resin or the like. At this point, the wax, the dispersant, and the plasticizer are in liquid form.

Next, this container is set in a rotation/revolution type stirring and defoaming apparatus, and the container is rotated and revolved for 3 minutes (a rotating and revolving kneading process) to stir the yttrium oxide powder, the wax, the dispersant and the plasticizer to obtain a slurry. Here, the particle size of the yttrium oxide powder may be adjusted so that the mean particle diameter (D₅₀) of the yttrium oxide powder after the rotating and revolving kneading process is, for example, 0.7 μm to 2 μm. Then, the obtained slurry is filled in a syringe, and the slurry is defoamed while rotating and revolving the syringe for 1 minute or more by using a defoaming tool.

Next, the syringe filled with the defoamed slurry is attached to an injection molding machine, and the slurry is supplied into an inner space of a molding die and molded while the temperature of the slurry is maintained at 90° C. or higher to obtain a cylindrical molded body. Here, the flow path the slurry of the injection molding machine passes through may also be maintained at 90° C. or higher. Further, the molding die includes an upper die, a lower die located opposite to the upper die, and a columnar core pin, and since the inner peripheral surface of the ceramic tube substantially transfers the outer peripheral surface of the core pin, to obtain a ceramic tube in which the section height difference (Rδc) of the roughness profile of the inner peripheral surface is 2 μm or less and the coefficient of variation of the section height difference (Rδc) is 0.05 to 0.6, the core pin in which a section height difference (Rδc) of the roughness profile of an outer peripheral surface, which represents the difference between a section level at a load length ratio of 25% in the roughness profile and the section level at a load length ratio of 75% in the roughness profile, is 2 μm or less and a coefficient of variation of the section height difference (Rδc) is 0.05 to 0.6 may be used.

To obtain a ceramic tube having a mean value of the root mean square slope (Rq) of 3.5 μm or less and a coefficient of variation of the root mean square slope (Rq) of 0.05 to 0.6 of the roughness profile, a core pin having a mean value of the root mean square slope (Rq) of 3.5 μm or less and a coefficient of variation of the root mean square slope (Rq) of 0.05 to 0.6 on the outer peripheral surface can be used.

A cylindrical sintered body can be obtained by sequentially degreasing and sintering the obtained molded product. Here, the sintering atmosphere may be an air atmosphere, the sintering temperature may be 1600° C. or higher and 1800° C. or lower, and the holding time may be 2 hours or longer and 4 hours or less.

The ceramic tube of the present disclosure can be obtained by grinding both end surfaces of the obtained sintered body.

To obtain a ceramic tube which contains a larger amount of yttrium aluminum oxide in the inner peripheral surface than the outer peripheral surface, or a ceramic tube wherein the maximum peak intensity I₁ on the inner peripheral surface of yttrium silicate (Y₂SiO₅) occurring at a diffraction angle 2θ of 30° to 32° is larger than the maximum peak intensity I₂ on the outer peripheral surface of yttrium silicate (Y₂SiO₅) occurring at a diffraction angle 2θ of 30° to 32°, at least the atmosphere surrounded by the inner peripheral surface of the molded body may be controlled to have less number of floating impurities than the atmosphere outside this range.

The present disclosure is not limited to the foregoing embodiment, and various changes, improvements, combinations, or the like can be made without departing from the scope of the present disclosure.

For example, in the example shown in FIGS. 1(a) and 1(b), the plasma-processing apparatus member 2a is arranged in the chamber 1 and is shown as the gas passage pipe 2a for generating stable plasma from the plasma generating gas G, but it may be a member that supplies the plasma generating gas G to the chamber 1, and a member that discharges the plasma generating gas G from the chamber 1.

### DESCRIPTION OF THE REFERENCE NUMERAL

1 chamber
2 upper electrode
2a plasma-processing apparatus member, gas passage pipe
2b electrode plate
2c diffusion part
2d introduction hole
2e holding member
2f shower plate
3 lower electrode
4 high frequency power supply
5 electrostatic chuck
10 plasma processing apparatus

1. A ceramic tube comprising yttrium oxide as a main component,
wherein the section height difference (Rδc) of the roughness profile of an inner peripheral surface, which represents a difference between a section level at a load length ratio of 25% in the roughness profile and a section level at a load length ratio of 75% in the roughness profile, is 2 μm or less, and a coefficient of variation of the section height difference (Rδc) is 0.05 to 0.6.

2. The ceramic tube according to claim 1, wherein a mean value of a root mean square slope (Rq) of the roughness profile is 3.5 μm or less, and a coefficient of variation of the root mean square slope (Rq) is 0.05 to 0.6.

3. The ceramic tube according to claim 1, wherein the content of yttrium oxide is 98.0% by mass or more.

4. The ceramic tube according to claim 1, comprising at least one of iron, cobalt and nickel, wherein the total content of the metal elements is 0.1% by mass or less.

5. The ceramic tube according to claim 1, wherein the inner peripheral surface contains more yttrium silicate than the outer peripheral surface located on the opposed side of the inner peripheral surface.

6. The ceramic tube according to claim 5, wherein a maximum peak intensity I1 on the inner peripheral surface of yttrium silicate (Y2SiO5) occurring at a diffraction angle 2θ of 30° to 32° is larger than a maximum peak intensity 12 on the outer peripheral surface of yttrium silicate (Y2SiO5) occurring at a diffraction angle 2θ of 30° to 32°.

7. A method for manufacturing the ceramic tube according to claim 1, comprising;
obtaining a slurry by containing a powder including yttrium oxide as a main component, a wax, a dispersant and a plasticizer in a container and conducting a kneading process,
supplying the slurry into a syringe for molding and deforming the slurry,
obtaining a cylindrical molded body by supplying the slurry into an inner space of a molding die from the syringe and molding it, and
obtaining a sintered body by sintering the molded body.

8. The method for manufacturing the ceramic tube according to claim 7, wherein the slurry is obtained by setting the container in which the raw materials are contained in a rotation/revolution type stirring and defoaming apparatus, and conducting a rotating and revolving kneading process.

9. A plasma processing apparatus comprising the ceramic tube according to claim 1.

10. The plasma processing apparatus according to claim 9, wherein the ceramic tube is a gas passage pipe arranged in a chamber for generating stable plasma from plasma generating gas.

11. The plasma processing apparatus according to claim 9, wherein the ceramic tube is at least one of a member that supplies the plasma generating gas to the chamber, and a member that discharges the plasma generating gas from the chamber.
